(19) United States
(12) Patent Application Publication
(10) Pub. No.: US 2026/0068150 A1
(43) Pub. Date: Mar. 5, 2026

(54) SEMICONDUCTOR STRUCTURE AND METHOD FOR MANUFACTURING SAME

(71) Applicant: CXMT Corporation, Hefei (CN)

(72) Inventors: Haoran LI, Hefei (CN); Zhi YANG, Hefei (CN)

(21) Appl. No.: 19/385,158

(22) Filed: Nov. 11, 2025

Related U.S. Application Data
(63) Continuation of application No. PCT/CN2023/131533, filed on Nov. 14, 2023.

(30) Foreign Application Priority Data
Jun. 25, 2023 (CN) 202310763715.1

(51) Int. Cl. H10B 12/00

(52) U.S. Cl. CPC H10B 12/50

(57) ABSTRACT

Provided are a semiconductor structure and a method for manufacturing the same. The semiconductor structure includes: a substrate, a first conductive layer, a second conductive layer, and isolation structure and a contact plug. The first conductive layer locates on the substrate and includes a first sub-conductive structure, a second sub-conductive structure, and a second conductive structure spaced apart from each other. The second conductive layer locates above the first conductive layer. The isolation structure locates between the first sub-conductive structure and the second sub-conductive structure, connects to the second conductive layer, and is configured to electrically isolate the first sub-conductive structure from the second sub-conductive structure. The contact plug locates between the second conductive structure and the second conductive layer and is configured to electrically connect the second conductive structure to the second conductive layer.

### CROSS-REFERENCE TO RELATED APPLICATIONS

The present disclosure is a continuation of International Patent Application No. PCT/CN2023/131533, filed on Nov. 14, 2023, which claims priority to Chinese Patent Application No. 202310763715.1, filed on Jun. 25, 2023, and entitled “SEMICONDUCTOR STRUCTURE AND METHOD FOR MANUFACTURING SAME”. The above-referenced application is incorporated herein by reference in their entireties.

### TECHNICAL FIELD

The present disclosure relates to the technical field of semiconductors, and particularly to a semiconductor structure and a method for manufacturing the same.

### BACKGROUND

In the evolution of the advanced dynamic random access memory (DRAM) process, the dimension of the core region where the metal layer is located continues to decrease with the decreasing dimension of the bit line/word line (BL/WL). Unlike a repeated layout of the line/space in an array region, the layout of a line in the metal layer in the core region is relatively complex. The increasingly smaller dimension leads to increased process difficulty and easily causes bridging problems between metal layers.

### SUMMARY

In view of this, the embodiments of the present disclosure provide a semiconductor structure and a method for manufacturing the same.

According to a first aspect of the embodiments of the present disclosure, a semiconductor structure is provided. The semiconductor structure includes: a substrate; a first conductive layer located on the substrate and including a first sub-conductive structure, a second sub-conductive structure, and a second conductive structure spaced apart from each other; a second conductive layer located above the first conductive layer; an isolation structure located between the first sub-conductive structure and the second sub-conductive structure, connected to the second conductive layer, and configured to electrically isolate the first sub-conductive structure from the second sub-conductive structure; and a contact plug located between the second conductive structure and the second conductive layer and configured to electrically connect the second conductive structure to the second conductive layer.

According to a second aspect of the embodiments of the present disclosure, a method for manufacturing a semiconductor structure is provided. The method includes: providing a substrate; forming an initial first conductive layer on the substrate, where the initial first conductive layer includes a first conductive structure and a second conductive structure spaced apart from each other; forming a first trench and a second trench in the same step, where the first trench penetrates through the first conductive structure to divide the first conductive structure into a first sub-conductive structure and a second sub-conductive structure, the second trench is located on the second conductive structure and exposes a part of the surface of the second conductive structure, and the first sub-conductive structure, the second sub-conductive structure, and the second conductive structure are formed as a first conductive layer; forming an isolation structure in the first trench; forming a contact plug in the second trench; and forming a second conductive layer on the isolation structure and the contact plug.

### BRIEF DESCRIPTION OF DRAWINGS

To more clearly illustrate technical solutions in embodiments of the present disclosure or the conventional technology, a brief introduction to the drawings required to be used in the embodiments is given hereinafter. It is evident that the drawings described hereinafter are merely some embodiments of the present disclosure. For those of ordinary skill in the art, other drawings may also be obtained based on these drawings without creative effort.

FIG. 1 is a schematic structural diagram of a semiconductor structure according to an embodiment of the present disclosure;

FIG. 2 is a top view of a semiconductor structure according to an embodiment of the present disclosure;

FIG. 3 is a schematic structural diagram of a semiconductor structure according to another embodiment of the present disclosure;

FIG. 4 is a flowchart of a method for manufacturing a semiconductor structure according to an embodiment of the present disclosure; and

FIG. 5a, FIG. 5b, FIG. 5c, FIG. 5d, FIG. 5e, FIG. 6a, FIG. 6b, FIG. 6c, FIG. 6d, FIG. 6e, FIG. 6f, FIG. 7a, FIG. 7b, FIG. 7c, FIG. 7d, FIG. 7e and FIG. 7f are schematic structural diagrams of a semiconductor structure in a manufacturing process according to an embodiment of the present disclosure.

Reference numerals in the figures are as follows:
substrate, 10; active region, 11; first source/drain region, 111; second source/drain region, 112; gate structure, 12; gate insulating layer, 121; first gate conductive layer, 122; second gate conductive layer, 123; third gate conductive layer, 124; cap layer, 125; gate spacer layer, 13;
first conductive layer, 20; first conductive structure, 21; first sub-conductive structure, 211; second sub-conductive structure, 212; second conductive structure, 22; initial first conductive layer pre-layer, 200′; initial first conductive layer, 200;
second conductive layer, 30; initial second conductive layer, 300;
isolation structure, 41; contact plug, 42; conductive pillar, 401; insulating layer, 402;
first dielectric layer, 51; first sub-dielectric layer, 511; second sub-dielectric layer, 512; second dielectric layer, 52; third dielectric layer, 53;
first connection pillar, 61; second connection pillar, 62;
first trench, 71; second trench, 72;
first isolation layer, 81; first mask layer, 82; and first pattern transfer layer, 83.

### DESCRIPTION OF EMBODIMENTS

Exemplary embodiments of the present disclosure will be described in more detail below with reference to the drawings. While exemplary embodiments of the present disclosure are shown in the drawings, it should be understood that the present disclosure may be implemented in various forms and should not be limited by the specific embodiments set forth herein. Rather, these embodiments are provided so that the present disclosure will be more thoroughly understood and the scope of the present disclosure will be fully conveyed to those skilled in the art.

In the following description, numerous specific details are set forth in order to provide a more thorough understanding of the present disclosure. However, it is apparent to those skilled in the art that the present disclosure can be implemented without one or more of these details. In other instances, some well-known technical features in the art are not described to avoid confusion with the present disclosure; i.e., not all features of the actual embodiments are described herein, and well-known functions and structures are not described in detail.

In the drawings, the dimensions of layers, regions, and elements, and their relative dimensions may be exaggerated for clarity. Identical reference numerals represent identical elements throughout the text.

It should be appreciated that when an element or a layer is referred to as being “on”, “adjacent to”, “connected to”, or “coupled to” another element or layer, it may be directly on, adjacent to, connected to, or coupled to the another element or layer, or an intervening element or layer may be present. On the contrary, when an element is referred to as being “directly on”, “directly adjacent to”, “directly connected to”, or “directly coupled to” another element or layer, no intervening element or layer is present. It should be appreciated that, although the terms first, second, third, etc., may be used to describe various elements, components, regions, layers, and/or parts, the elements, components, regions, layers, and/or parts should not be limited by these terms. These terms are only used to distinguish one element, component, region, layer, or part from another element, component, region, layer, or part. Therefore, a first element, component, region, layer, or part discussed below may be termed a second element, component, region, layer, or part without departing from the teachings of the present disclosure. However, the discussion of a second element, component, region, layer, or part does not necessarily imply that a first element, component, region, layer, or part is necessarily present in the present disclosure.

Spatial relationship terms, e.g., “under”, “below”, “underneath”, “beneath”, “on”, “above”, and the like, may be used herein for ease of description to describe the relationship between an element or a feature and other elements or features shown in the figures. It should be appreciated that the spatial relationship terms are intended to encompass different orientations of the device in use or operation in addition to the orientations depicted in the figures. For example, if the device in the figures is turned over, elements or features described as being “below”, “beneath”, or “under” other elements or features would then be oriented “above” the other elements or features. Therefore, the exemplary terms “below” and “under” may include both up and down orientations. A device may be otherwise oriented (rotated 90 degrees or at other orientations) and the spatial descriptors used herein may be interpreted accordingly.

The terms used herein are for the purpose of describing specific embodiments only and should not be construed as limiting the present disclosure. As used herein, the singular forms “a”, “an”, and “the” are intended to include the plural forms as well, unless the context clearly indicates otherwise. It should be further appreciated that the terms “comprise” and/or “include”, when used in this specification, specify the presence of stated features, integers, steps, operations, elements, and/or components, but do not preclude the presence or addition of one or more other features, integers, steps, operations, elements, components, and/or groups. As used herein, the term “and/or” includes any and all combinations of the associated listed items.

In order to thoroughly understand the present disclosure, detailed steps and structures will be set forth in the following description so as to explain the technical solutions of the present disclosure. The preferred embodiments of the present disclosure are described in detail below; however, the present disclosure can be practiced otherwise than as specifically described.

In the related art, firstly, a first conductive layer is formed by using a self-aligned double patterning (Self-Aligned Double Patterning, SADP) technology, and then a dielectric layer is deposited, followed by the formation of a contact plug and a second conductive layer. This involves multiple processes, resulting in an increase in costs.

Based on this, the embodiments of the present disclosure provide a semiconductor structure. FIG. 1 is a schematic structural diagram of a semiconductor structure according to an embodiment of the present disclosure.

Referring to FIG. 1, the semiconductor structure includes:
a substrate 10;
a first conductive layer 20 located on the substrate 10 and including a first sub-conductive structure 211, a second sub-conductive structure 212, and a second conductive structure 22 spaced apart from each other;
a second conductive layer 30 located above the first conductive layer 20;
an isolation structure 41 located between the first sub-conductive structure 211 and the second sub-conductive structure 212, connected to the second conductive layer 30, and configured to electrically isolate the first sub-conductive structure 211 from the second sub-conductive structure 212; and
a contact plug 42 located between the second conductive structure 22 and the second conductive layer 30 and configured to electrically connect the second conductive structure 22 to the second conductive layer 30.

In the embodiments of the present disclosure, the isolation structure, the contact plug, and the first conductive layer can be formed in the same process, thereby simplifying the process and saving costs. Meanwhile, the isolation structure electrically isolates the first sub-conductive structure from the second sub-conductive structure to avoid crosstalk.

In an embodiment, the substrate 10 may be a silicon substrate, a germanium substrate, a silicon-germanium substrate, a silicon carbide substrate, a silicon on insulator (silicon on insulator, SOI) substrate, a germanium on insulator (germanium on insulator, GOI) substrate, or the like; or may be a substrate including other elemental semiconductors or compound semiconductors, such as a glass substrate or a group III-V compound substrate (e.g., a gallium nitride substrate or a gallium arsenide substrate); or may be a stack structure, such as Si/SiGe; or may be other epitaxial structures, such as silicon-germanium on insulator (SGOI).

The substrate 10 includes an active region 11 and a gate structure 12 located on the active region 11. The active region 11 includes a first source/drain region 111 and a second source/drain region 112 located on opposite sides of the gate structure 12, respectively. The substrate further includes an isolation region (not shown in the figure) adjacent to the active region 11. The isolation region defines the substrate as a plurality of discrete active regions 11.

The gate structure 12 includes a gate insulating layer 121, a first gate conductive layer 122, a second gate conductive layer 123, a third gate conductive layer 124, and a cap layer 125 sequentially stacked from bottom to top. The material of the gate insulating layer 121 includes, but is not limited to, an oxide; the material of the first gate conductive layer 122 includes, but is not limited to, polycrystalline silicon; the material of the second gate conductive layer 123 includes, but is not limited to, titanium nitride; the material of the third gate conductive layer 124 includes, but is not limited to, metal tungsten; the material of the cap layer 125 includes, but is not limited to, an oxide, a nitride, a metal oxide, an oxynitride, and the like.

In an embodiment, the semiconductor structure further includes a gate spacer layer 13. The gate spacer layer 13 covers a side wall of the gate structure 12 to insulate and isolate the gate structure 12 from a first connection pillar 61 and a second connection pillar 62.

Referring to FIG. 1, the first conductive layer 20 includes the first sub-conductive structure 211, the second sub-conductive structure 212, and the second conductive structure 22 spaced apart from each other.

The material of the first conductive layer 20 includes, but is not limited to, tungsten (W), copper (Cu), titanium (Ti), tantalum (Ta), titanium nitride (TiN), tantalum nitride (TaN), a metal silicide, a metal alloy, or any combination thereof.

In an embodiment, the semiconductor structure further includes a first connection pillar 61 and a second connection pillar 62. The first connection pillar 61 electrically connects the first sub-conductive structure 211 to the first source/drain region 111, and the second connection pillar 62 electrically connects the second sub-conductive structure 212 to the second source/drain region 112.

In an embodiment, the semiconductor structure further includes: a first dielectric layer 51 located on the substrate 10 and including a first sub-dielectric layer 511 and a second sub-dielectric layer 512, where the first sub-dielectric layer 511 is located on the side wall of the first conductive layer 20 and below the first conductive layer, and the second sub-dielectric layer 512 covers the first conductive layer 20 and the first sub-dielectric layer 511; and a second dielectric layer 52 located on the first dielectric layer 51.

With further reference to FIG. 1, the second conductive layer 30 is located above the first conductive layer 20. Specifically, the second conductive layer 30 is located on the second dielectric layer 52.

The material of the second conductive layer 30 includes, but is not limited to, tungsten (W), copper (Cu), titanium (Ti), tantalum (Ta), titanium nitride (TiN), tantalum nitride (TaN), a metal silicide, a metal alloy, or any combination thereof.

With further reference to FIG. 1, the isolation structure 41 is located between the first sub-conductive structure 211 and the second sub-conductive structure 212, is connected to the second conductive layer 30, and is configured to electrically isolate the first sub-conductive structure 211 from the second sub-conductive structure 212. The contact plug 42 is located between the second conductive structure 22 and the second conductive layer 30 and is configured to electrically connect the second conductive structure 22 to the second conductive layer 30.

In some embodiments, the bottom surface of the contact plug 42 is flush with the top surface of the second conductive structure 22, that is, the contact plug 42 does not extend into the second conductive structure 22.

In some other embodiments, the bottom surface of the contact plug 42 is lower than the top surface of the second conductive structure 22 and the bottom surface of the contact plug 42 is higher than the bottom surface of the second conductive structure 22, that is, the contact plug extends into the second conductive structure 22 but does not penetrate through the second conductive structure 22.

In an embodiment, the top surface of the isolation structure 41 is flush with the top surface of the contact plug 42, the bottom surface of the isolation structure 41 is lower than the bottom surface of the contact plug 42, and the bottom surface of the isolation structure 41 is not higher than the bottom surface of the first conductive layer 20.

Specifically, in some embodiments, as shown in FIG. 1, the bottom surface of the isolation structure 41 is lower than the bottom surface of the first conductive layer 20. In some other embodiments, the bottom surface of the isolation structure 41 is flush with the bottom surface of the first conductive layer 20. The bottom surface of the isolation structure 41 may be lower than or flush with the bottom surface of the first conductive layer 20, as long as the isolation structure 41 can insulate and isolate the first sub-conductive structure 211 from the second sub-conductive structure 212.

In an embodiment, the isolation structure 41 and the contact plug 42 each include a conductive pillar 401 and an insulating layer 402 disposed around the side wall of the conductive pillar 401.

In the isolation structure 41, the insulating layer 402 is in contact with the first sub-conductive structure 211 and the second sub-conductive structure 212 to achieve an insulation and isolation effect, and the conductive pillar 401 is not in contact with the first sub-conductive structure 211 and the second sub-conductive structure 212. Therefore, even if the isolation structure 41 includes the conductive pillar 401, the isolation structure 41 does not play a conductive role. For the contact plug 42, since the bottom surface and the top surface of the conductive pillar 401 are in contact with the second conductive structure 22 and the second conductive layer 30, respectively, and the insulating layer 402 is located at the side wall of the conductive pillar 401, the conductivity of the contact plug 42 is not affected. In addition, the conductive pillar and the insulating layer that constitute the isolation structure and the contact plug may be synchronously formed in the same step, thereby simplifying process steps and reducing costs.

In some other embodiments, the isolation structure 41 may include only the insulating layer 402, and the contact plug includes only the conductive pillar 401.

As shown in FIG. 1, the conductive pillar 401 may include a two-layer structure, which includes a first conductive pillar (not shown in the figure) and a diffusion barrier layer (not shown in the figure) located between the first conductive pillar and the insulating layer. The diffusion barrier layer may also be located between the second conductive layer and the second dielectric layer. For example, the first conductive pillar is made of a metal material such as tungsten or copper, and the diffusion barrier layer is made of titanium nitride.

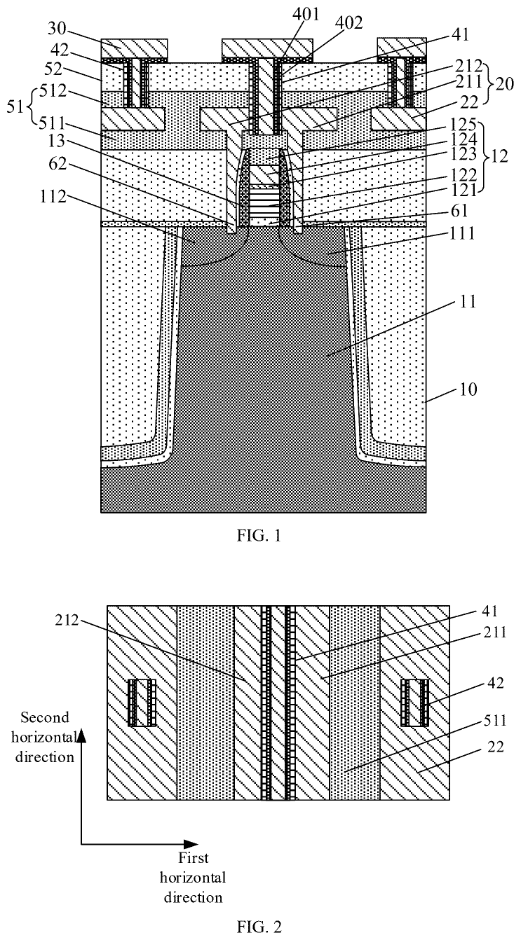

FIG. 2 is a top view of a semiconductor structure according to an embodiment of the present disclosure. However, it should be noted that FIG. 2 is a top view after the second conductive layer, the second dielectric layer, and the second sub-dielectric layer are removed, and is mainly to show the positional relationship between the isolation structure 41 and the first conductive layer 20, as well as between the contact plug 42 and the first conductive layer.

In an embodiment, as shown in FIG. 2, the dimension of the isolation structure 41 in a first horizontal direction is greater than the dimension of the contact plug 42 in the first horizontal direction, and the dimension of the isolation structure 41 in a second horizontal direction is greater than or equal to the dimensions of the first sub-conductive structure 211 and the second sub-conductive structure 212 in the second horizontal direction. The first horizontal direction is an arrangement direction of the first sub-conductive structure 211 and the second sub-conductive structure 212, and the second horizontal direction is an extension direction of the first sub-conductive structure 211 and the second sub-conductive structure 212.

The dimension of the isolation structure 41 in the first horizontal direction is greater than the dimension of the contact plug 42 in the first horizontal direction, that is, when a first trench and a second trench for forming the isolation structure 41 and the contact plug 42, respectively, are etched, the width of the first trench is greater than the width of the second trench. In this way, due to the etch loading effect of the dielectric layer, the first trench with a larger width can be etched faster. Thus, when the first trench penetrates through the first conductive layer 20, the second trench may remain at the surface or interior of the first conductive layer 20 without penetrating through the first conductive layer 20.

The dimension of the isolation structure 41 in the second horizontal direction is greater than or equal to the dimensions of the first sub-conductive structure 211 and the second sub-conductive structure 212 in the second horizontal direction, such that the isolation structure 41 can completely isolate the first sub-conductive structure 211 from the second sub-conductive structure 212, thereby achieving an insulation and isolation effect.

In some embodiments, the sum of the dimension of the second sub-dielectric layer 512 along the thickness direction of the substrate 10 and the dimension of the second dielectric layer 52 along the thickness direction of the substrate 10 is greater than or equal to a preset value.

The isolation structure 41 penetrates through the second dielectric layer 52 and the second sub-dielectric layer 512, and extends into the first sub-dielectric layer 511.

The contact plug 42 penetrates through the second dielectric layer 52 and the second sub-dielectric layer 512, and is in contact with the second conductive structure 22.

When the sum of the dimension of the second sub-dielectric layer 512 along the thickness direction of the substrate and the dimension of the second dielectric layer 52 along the thickness direction of the substrate is greater than or equal to the preset value (the preset value is greater than one tenth of the height of the contact plug 42 and may be, for example, 20 nm), it is indicated that the overall thickness of the dielectric layer is sufficiently large, such that there is sufficient margin for utilizing the loading effect to etch the first trench and the second trench to different depths, and thereby the second trench with a smaller width is not etched through the second sub-dielectric layer while the first trench with a larger width is etched through the second sub-dielectric layer.

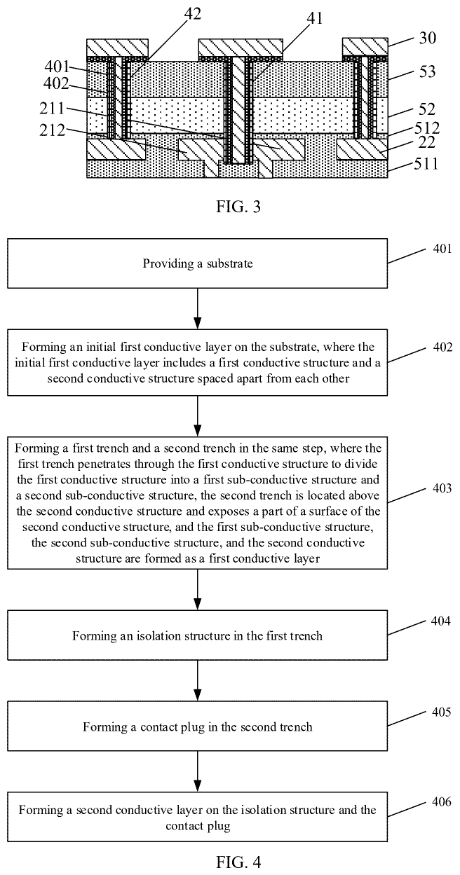

FIG. 3 is a schematic structural diagram of a semiconductor structure according to another embodiment of the present disclosure. It should be noted that the substrate is not shown in FIG. 3.

In some other embodiments, as shown in FIG. 3, the sum of the dimension of the second sub-dielectric layer 512 along the thickness direction of the substrate 10 and the dimension of the second dielectric layer 52 along the thickness direction of the substrate 10 is less than a preset value.

The semiconductor structure further includes a third dielectric layer 53 located on the second dielectric layer 52.

The isolation structure 41 penetrates through the third dielectric layer 53, the second dielectric layer 52, and the second sub-dielectric layer 512, and extends into the first sub-dielectric layer 511.

The contact plug 42 penetrates through the third dielectric layer 53, the second dielectric layer 52, and the second sub-dielectric layer 512, and is in contact with the second conductive structure 22.

When the sum of the dimension of the second sub-dielectric layer 512 along the thickness direction of the substrate and the dimension of the second dielectric layer 52 along the thickness direction of the substrate is less than the preset value, it is indicated that the sum of the thicknesses of the second sub-dielectric layer 512 and the second dielectric layer 52 is not enough, such that there is no way to utilize the loading effect to etch the first trench and the second trench to different depths. Therefore, the third dielectric layer is added to increase the overall thickness of the dielectric layer (the sum of the second sub-dielectric layer, the second dielectric layer, and the third dielectric layer), thereby ensuring sufficient margin for utilizing the loading effect to etch the first trench and the second trench to different depths.

In an embodiment, the materials of the first dielectric layer 51 and the second dielectric layer 52 are different, and the materials of the second dielectric layer 52 and the third dielectric layer 53 are different.

The materials of the first dielectric layer 51 and the second dielectric layer 52 are different, and the materials of the second dielectric layer 52 and the third dielectric layer 53 are different, such that it can be ensured that the first dielectric layer 51 has a different etching selectivity from the second dielectric layer 52, and the second dielectric layer 52 has a different etching selectivity from the third dielectric layer 53. Thus, in the process of etching the first trench and the second trench, when the first trench is etched through the first conductive layer, the second trench may remain at the surface or interior of the first conductive layer.

The material of the first dielectric layer 51 includes, but is not limited to, a nitride, the material of the second dielectric layer 52 includes, but is not limited to, an oxide, and the material of the third dielectric layer 53 includes, but is not limited to, a nitride.

In some other embodiments, the first trench and the second trench may be formed separately in sequence to more accurately control the depths of the first trench and the second trench. For example, the first trench is formed by etching first, then the first trench is filled with a sacrificial material, and the sacrificial material is removed after the second trench is formed by etching. Alternatively, the second trench is formed by etching first, then the second trench is filled with a sacrificial material, and the sacrificial material is removed after the first trench is formed by etching.

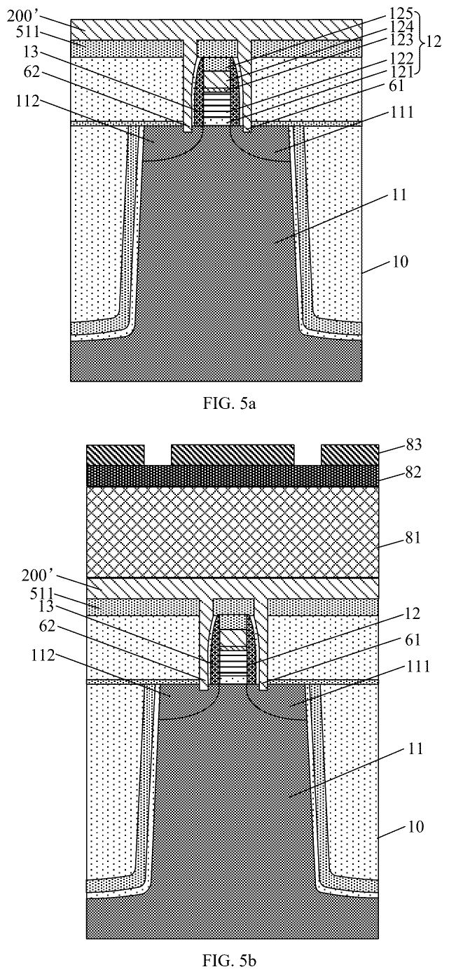

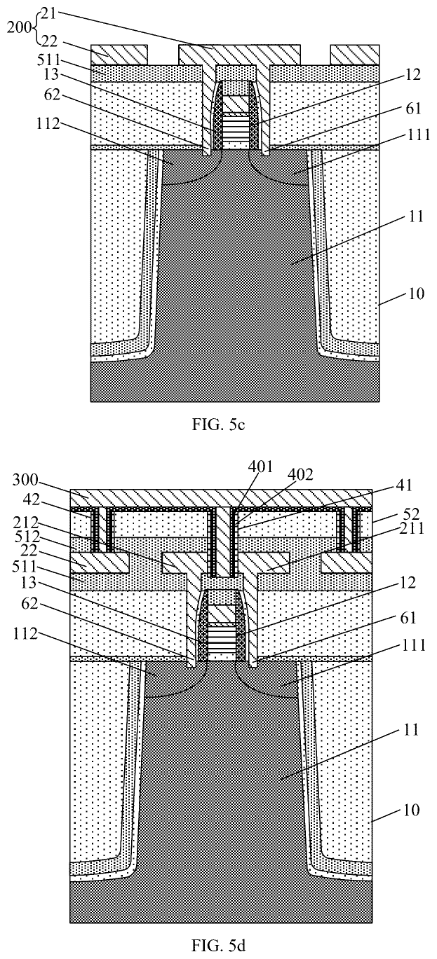

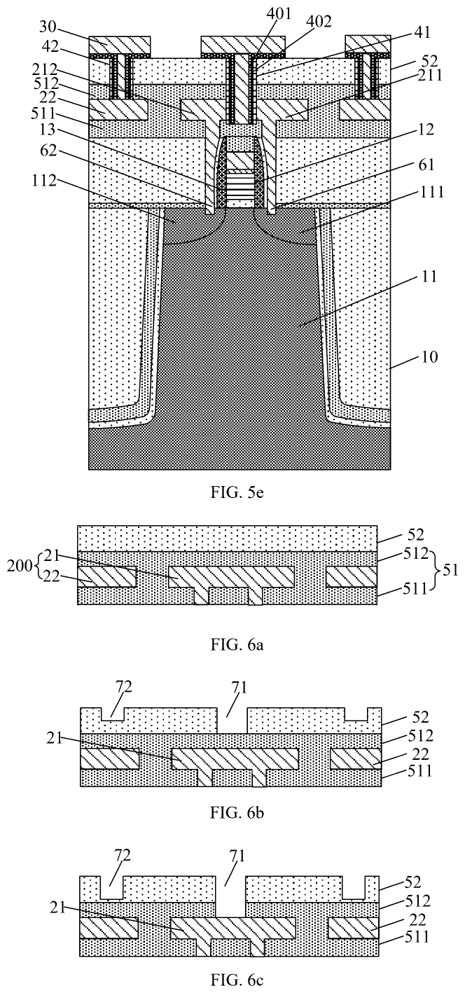

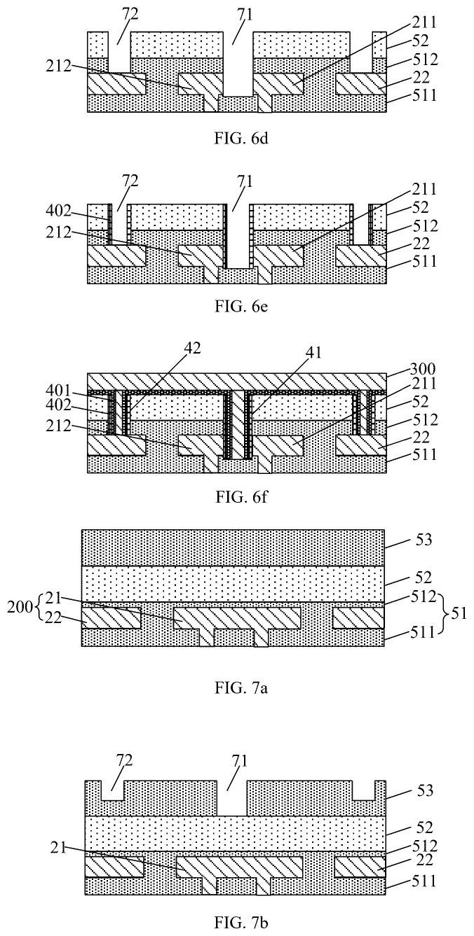

The embodiments of the present disclosure further provide a method for manufacturing a semiconductor structure. Reference is made to FIG. 4 for details. Referring to FIG. 4, the method includes the following steps.

In step 401, a substrate is provided.

In step 402, an initial first conductive layer is formed on the substrate. The initial first conductive layer includes a first conductive structure and a second conductive structure spaced apart from each other.

In step 403, a first trench and a second trench are formed in the same step. The first trench penetrates through the first conductive structure to divide the first conductive structure into a first sub-conductive structure and a second sub-conductive structure. The second trench is located on the second conductive structure and exposes a part of the surface of the second conductive structure. The first sub-conductive structure, the second sub-conductive structure, and the second conductive structure are formed as a first conductive layer.

In step 404, an isolation structure is formed in the first trench.

In step 405, a contact plug is formed in the second trench.

In step 406, a second conductive layer is formed on the isolation structure and the contact plug.

The method for manufacturing the semiconductor structure according to the embodiments of the present disclosure will be further described in detail below with reference to specific embodiments.

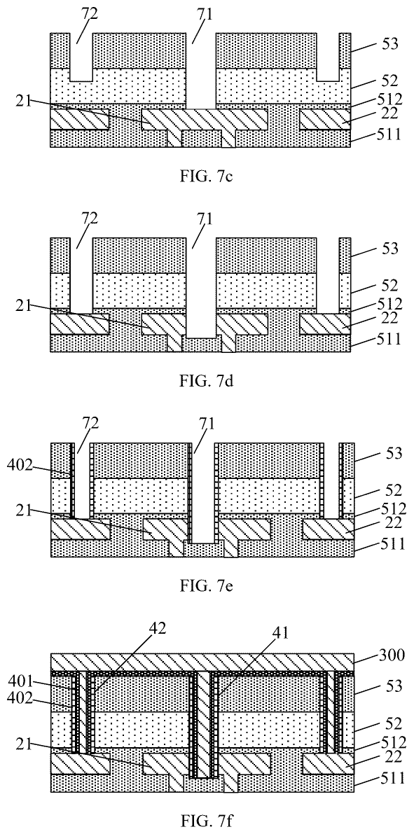

FIG. 5a to FIG. 7f are schematic structural diagrams of a semiconductor structure in a manufacturing process according to an embodiment of the present disclosure.

First, referring to FIG. 5a, step 401 is performed, in which a substrate 10 is provided.

In an embodiment, the substrate 10 may be a silicon substrate, a germanium substrate, a silicon-germanium substrate, a silicon carbide substrate, a silicon on insulator (silicon on insulator, SOI) substrate, a germanium on insulator (germanium on insulator, GOI) substrate, or the like; or may be a substrate including other elemental semiconductors or compound semiconductors, such as a glass substrate or a group III-V compound substrate (e.g., a gallium nitride substrate or a gallium arsenide substrate); or may be a stack structure, such as Si/SiGe; or may be other epitaxial structures, such as silicon-germanium on insulator (SGOI).

The substrate 10 includes an active region 11 and a gate structure 12 located on the active region 11. The active region 11 includes a first source/drain region 111 and a second source/drain region 112 located on opposite sides of the gate structure 12, respectively. The substrate 10 further includes an isolation region (not shown in the figure). The isolation region defines the substrate as a plurality of discrete active regions 11.

The gate structure 12 includes a gate insulating layer 121, a first gate conductive layer 122, a second gate conductive layer 123, a third gate conductive layer 124, and a cap layer 125 sequentially stacked from bottom to top. The material of the gate insulating layer 121 includes, but is not limited to, an oxide; the material of the first gate conductive layer 122 includes, but is not limited to, polycrystalline silicon; the material of the second gate conductive layer 123 includes, but is not limited to, titanium nitride; the material of the third gate conductive layer 124 includes, but is not limited to, metal tungsten; the material of the cap layer 125 includes, but is not limited to, an oxide, a nitride, a metal oxide, an oxynitride, and the like.

In an embodiment, a gate spacer layer 13 covering the side wall of the gate structure 12 is formed to insulate and isolate the gate structure 12 from the subsequently formed first connection pillar 61 and second connection pillar 62.

Next, referring to FIG. 5a to FIG. 5c, step 402 is performed, in which an initial first conductive layer 200 is formed on the substrate 10. The initial first conductive layer 200 includes a first conductive structure 21 and a second conductive structure 22 spaced apart from each other.

In an embodiment, forming the initial first conductive layer 200 on the substrate 10 includes: forming a first connection pillar 61 and a second connection pillar 62, and the initial first conductive layer 200 on the first connection pillar 61 and the second connection pillar 62. The first connection pillar 61 is in contact with the first source/drain region 111, and the second connection pillar 62 is in contact with the second source/drain region 112.

Specifically, referring to FIGS. 5a and 5b, the method further includes: before forming the initial first conductive layer 200, forming an initial first conductive layer pre-layer 200′ on the substrate 10, and forming a first isolation layer 81, a first mask layer 82, and a first pattern transfer layer 83 on the initial first conductive layer pre-layer 200′. The first isolation layer 81, the first mask layer 82, and the first pattern transfer layer 83 may be used as a mask for subsequently forming the initial first conductive layer 200.

In actual operation, the initial first conductive layer pre-layer 200′, the first isolation layer 81, the first mask layer 82, and the first pattern transfer layer 83 may be formed by using one or more thin film deposition processes. Specifically, the deposition process includes, but is not limited to, a chemical vapor deposition (CVD) process, an atomic layer deposition (ALD) process, or a combination thereof.

The material of the first isolation layer 81 includes, but is not limited to, amorphous carbon (ACL), the material of the first mask layer 82 includes, but is not limited to, silicon oxynitride, and the material of the first pattern transfer layer 83 includes, but is not limited to, photoresist. The material of the initial first conductive layer pre-layer 200′ includes, but is not limited to, tungsten (W), copper (Cu), titanium (Ti), tantalum (Ta), titanium nitride (TiN), tantalum nitride (TaN), a metal silicide, a metal alloy, or any combination thereof.

Referring to FIG. 5c, the first pattern transfer layer 83 has a pattern structure. The initial first conductive layer pre-layer 200′ is etched according to the pattern structure on the first pattern transfer layer 83 to form the initial first conductive layer 200.

The initial first conductive layer 200 includes the first conductive structure 21 and the second conductive structure 22. The first connection pillar 61 and the second connection pillar 62 are connected to the first conductive structure 21.

Next, referring to FIG. 5d, FIG. 6a to FIG. 6f, and FIG. 7a to FIG. 7f, step 403 to step 405 are performed, in which: a first trench 71 and a second trench 72 are formed in the same step, where the first trench 71 penetrates through the first conductive structure 21 to divide the first conductive structure 21 into a first sub-conductive structure 211 and a second sub-conductive structure 212, the second trench 72 is located above the second conductive structure 22 and exposes a part of the surface of the second conductive structure 22, and the first sub-conductive structure 211, the second sub-conductive structure 212, and the second conductive structure 22 are formed as a first conductive layer 20; an isolation structure 41 is formed in the first trench 71; a contact plug 42 is formed in the second trench 72.

It should be noted that FIG. 6a to FIG. 6f are schematic diagrams of a semiconductor structure in a manufacturing process according to an embodiment, and FIG. 7a to FIG. 7f are schematic diagrams of a semiconductor structure in a manufacturing process according to another embodiment. Firstly, the embodiment shown in FIG. 6a to FIG. 6f will be described below in detail.

Referring to FIG. 6a first, the above method further includes: before forming the initial first conductive layer 200, forming a first sub-dielectric layer 511 on the substrate 10, where the first sub-dielectric layer 511 is located on the side wall of the initial first conductive layer 200 and below the initial first conductive layer;
forming a second sub-dielectric layer 512 covering the initial first conductive layer 200 and the first sub-dielectric layer 511, where the first sub-dielectric layer 511 and the second sub-dielectric layer 512 are formed as a first dielectric layer 51; and
forming a second dielectric layer 52 on the first dielectric layer 51.

In an embodiment, the materials of the first dielectric layer 51 and the second dielectric layer 52 are different. The material of the first dielectric layer 51 includes, but is not limited to, a nitride, and the material of the second dielectric layer 52 includes, but is not limited to, an oxide.

Next, referring to FIG. 6b to FIG. 6d, the sum of the dimension of the second sub-dielectric layer 512 along the thickness direction of the substrate 10 and the dimension of the second dielectric layer 52 along the thickness direction of the substrate 10 is greater than or equal to a preset value.

Forming the first trench 71 and the second trench 72 in the same step includes:
referring to FIG. 6b, performing a first etching process, where the first trench 71 penetrates through the second dielectric layer 52 and stops at the surface of the first dielectric layer 51, the second trench 72 stops within the second dielectric layer 52, the dimension of the first trench 71 in a first horizontal direction is greater than the dimension of the second trench 72 in the first horizontal direction, and the first horizontal direction is an arrangement direction of the first sub-conductive structure 211 and the second sub-conductive structure 212;
referring to FIG. 6c, performing a second etching process, where the first trench 71 penetrates through the second sub-dielectric layer 512 and stops at the surface of the first conductive structure 21, the second trench 72 stops within the second dielectric layer 52, and the first dielectric layer 51 has a different etching selectivity from the second dielectric layer 52; and
referring to FIG. 6d, performing a third etching process, where the first trench 71 penetrates through the first conductive structure 21, and the second trench 72 exposes the part of the surface of the second conductive structure 22.

In this embodiment, when the sum of the dimension of the second sub-dielectric layer 512 along the thickness direction of the substrate and the dimension of the second dielectric layer 52 along the thickness direction of the substrate is greater than or equal to the preset value, it is indicated that the overall thickness of the dielectric layer is sufficiently large, such that there is sufficient margin for utilizing the loading effect to etch the first trench 71 and the second trench 72 to different depths, and thereby the second trench 72 with a smaller width is not etched through the second sub-dielectric layer 512 while the first trench 71 with a larger width is etched through the second sub-dielectric layer 512.

In addition, the first dielectric layer 51 has a different etching selectivity from the second dielectric layer 52, such that in the process of etching the first trench 71 and the second trench 72, when the first trench 71 is etched through the first conductive structure 21, the second trench 72 may remain at the surface or interior of the second conductive structure 22.

Next, referring to FIGS. 6e and 6f, forming the isolation structure 41 in the first trench 71 and forming the contact plug 42 in the second trench 72 include:
forming an insulating layer 402 on the side walls of the first trench 71 and the second trench 72; and
filling a conductive material into the first trench 71 and the second trench 72, both of which are formed with the insulating layer 402, to form the isolation structure 41 in the first trench 71 and form the contact plug 42 in the second trench 72.

Specifically, the insulating layer 402 is first formed at the side walls of the first trench 71 and the second trench 72, and then a conductive pillar 401 covering the insulating layer 402 is formed.

The insulating layer 402 in the isolation structure 41 is in contact with the first sub-conductive structure 211 and the second sub-conductive structure 212 to achieve an insulation and isolation effect. Therefore, even if the isolation structure 41 includes the conductive pillar 401, the isolation structure 41 does not play a conductive role. For the contact plug 42, since the bottom surface and the top surface are in contact with the second conductive structure 22 and the second conductive layer 30, respectively, and the insulating layer 402 is located at the side wall, the conductivity of the contact plug 42 is not affected. In addition, the conductive pillar and the insulating layer may be formed in the isolation structure and the contact plug in the same step, thereby simplifying process steps and reducing costs.

As shown in FIG. 6f, the conductive pillar 401 may include a two-layer structure, which includes a first conductive pillar (not shown in the figure) and a diffusion barrier layer (not shown in the figure) located between the first conductive pillar and the insulating layer. The diffusion barrier layer may further cover the surface of the second dielectric layer.

In this embodiment, the isolation structure 41 and the contact plug 42 each include the conductive pillar 401 and the insulating layer 402.

In some other embodiments, the isolation structure 41 may include only the insulating layer 402, and the contact plug 42 may include only the conductive pillar 401.

In some embodiments, the bottom surface of the contact plug 42 is flush with the top surface of the second conductive structure 22, that is, the contact plug 42 does not extend into the second conductive structure 22.

In some other embodiments, the bottom surface of the contact plug 42 is lower than the top surface of the second conductive structure 22, that is, the contact plug 42 extends into the second conductive structure 22.

In an embodiment, the top surface of the isolation structure 41 is flush with the top surface of the contact plug 42, the bottom surface of the isolation structure 41 is lower than the bottom surface of the contact plug 42, and the bottom surface of the isolation structure 41 is not higher than the bottom surface of the first conductive layer 20.

Specifically, in some embodiments, as shown in FIG. 6f, the bottom surface of the isolation structure 41 is lower than the bottom surface of the first conductive layer 20. In some other embodiments, the bottom surface of the isolation structure 41 is flush with the bottom surface of the first conductive layer 20. The bottom surface of the isolation structure 41 may be lower than or flush with the bottom surface of the first conductive layer 20, as long as the isolation structure 41 can insulate and isolate the first sub-conductive structure 211 from the second sub-conductive structure 212.

In an embodiment, as shown in FIG. 2, the dimension of the isolation structure 41 in a first horizontal direction is greater than the dimension of the contact plug 42 in the first horizontal direction, and the dimension of the isolation structure 41 in a second horizontal direction is greater than or equal to the dimensions of the first sub-conductive structure 211 and the second sub-conductive structure 212 in the second horizontal direction. The first horizontal direction is an arrangement direction of the first sub-conductive structure 211 and the second sub-conductive structure 212, and the second horizontal direction is an extension direction of the first sub-conductive structure 211 and the second sub-conductive structure 212.

The dimension of the isolation structure 41 in the first horizontal direction is greater than the dimension of the contact plug 42 in the first horizontal direction, that is, when the first trench 71 and the second trench 72 for forming the isolation structure 41 and the contact plug 42, respectively, are etched, the width of the first trench 71 is greater than the width of the second trench 72. In this way, due to the etch loading effect of the dielectric layer, the first trench 71 with a larger width can be etched faster. Thus, when the first trench penetrates through the first conductive layer 20, the second trench 72 may remain at the surface or interior of the first conductive layer 20 without penetrating through the first conductive layer.

The dimension of the isolation structure 41 in the second horizontal direction is greater than or equal to the dimensions of the first sub-conductive structure 211 and the second sub-conductive structure 212 in the second horizontal direction, such that the isolation structure 41 can completely isolate the first sub-conductive structure 211 from the second sub-conductive structure 212, thereby achieving an insulation and isolation effect.

With further reference to FIG. 6f, an initial second conductive layer 300 is formed on the second dielectric layer 52 while the conductive pillar 401 is formed.

Next, the embodiment shown in FIG. 7a to FIG. 7f will be described in detail.

The sum of the dimension of the second sub-dielectric layer 512 along the thickness direction of the substrate 10 and the dimension of the second dielectric layer 52 along the thickness direction of the substrate 10 is less than a preset value.

The method further includes:
referring to FIG. 7a, forming a third dielectric layer 53 on the second dielectric layer 52.

Forming the first trench 71 and the second trench 72 in the same step includes:
referring to FIG. 7b, performing a fourth etching process, where the first trench 71 penetrates through the third dielectric layer 53 and stops at the surface of the second dielectric layer 52, the second trench 72 stops within the third dielectric layer 53, the dimension of the first trench 71 in a first horizontal direction is greater than the dimension of the second trench 72 in the first horizontal direction, and the first horizontal direction is an arrangement direction of the first sub-conductive structure 211 and the second sub-conductive structure 212;
referring to FIG. 7c, performing a fifth etching process, where the first trench 71 penetrates through the second dielectric layer 52 and the second sub-dielectric layer 512 and stops at the surface of the first conductive structure 21, the second trench 72 penetrates through the third dielectric layer 53 and stops within the second dielectric layer 52, and the second dielectric layer 52 has a different etching selectivity from the third dielectric layer 53; and
referring to FIG. 7d, performing a sixth etching process, where the first trench 71 penetrates through the first conductive structure 21, and the second trench 72 exposes the part of the surface of the second conductive structure 22.

When the sum of the dimension of the second sub-dielectric layer 512 along the thickness direction of the substrate and the dimension of the second dielectric layer 52 along the thickness direction of the substrate is less than the preset value, it is indicated that the sum of the thicknesses of the second sub-dielectric layer 512 and the second dielectric layer 52 is not enough, such that there is no way to utilize the loading effect to etch the first trench and the second trench to different depths. Therefore, the third dielectric layer 53 is added to increase the overall thickness of the dielectric layer, thereby ensuring sufficient margin for utilizing the loading effect to etch the first trench and the second trench to different depths.

In an embodiment, the materials of the first dielectric layer 51 and the second dielectric layer 52 are different, and the materials of the second dielectric layer 52 and the third dielectric layer 53 are different. The material of the first dielectric layer 51 includes, but is not limited to, a nitride, the material of the second dielectric layer 52 includes, but is not limited to, an oxide, and the material of the third dielectric layer 53 includes, but is not limited to, a nitride.

Next, referring to FIGS. 7e and 7f, the isolation structure 41 is formed in the first trench 71, and the contact plug 42 is formed in the second trench 72. The steps of forming the isolation structure 41 and the contact plug 42 in this embodiment are the same as those in FIGS. 6e and 6f, and details are not described herein again.

Next, referring to FIG. 5e, step 406 is performed, in which the second conductive layer 30 is formed on the isolation structure 41 and the contact plug 42.

Specifically, a mask layer may be first deposited on the upper surface of the initial second conductive layer 300. Then, the mask layer is patterned to present, on the mask layer, a pattern of the second conductive layer to be etched. The mask layer may be patterned by a photolithography process. The mask layer may be a photoresist mask, or a hard mask patterned based on a photolithography mask. When the mask layer is a photoresist mask, the mask layer is specifically patterned through steps such as exposure, development, and photoresist removal. Then, the second conductive layer 30 is etched according to the pattern of the second conductive layer 30 to be etched.

The material of the second conductive layer 30 includes, but is not limited to, tungsten (W), copper (Cu), titanium (Ti), tantalum (Ta), titanium nitride (TiN), tantalum nitride (TaN), a metal silicide, a metal alloy, or any combination thereof.

The above descriptions are merely preferred embodiments of the present disclosure, and are not intended to limit the protection scope of the present disclosure. Any modification, equivalent replacement, or improvement made within the spirit and principle of the present disclosure shall fall within the protection scope of the present disclosure.

### INDUSTRIAL APPLICABILITY

In the embodiments of the present disclosure, the isolation structure, the contact plug, and the first conductive layer can be formed in the same process, thereby simplifying the process and saving costs. Meanwhile, the isolation structure electrically isolates the first sub-conductive structure from the second sub-conductive structure to avoid crosstalk.

What is claimed is:

1. A semiconductor structure, comprising:
a substrate;
a first conductive layer located on the substrate and comprising a first sub-conductive structure, a second sub-conductive structure, and a second conductive structure spaced apart from each other;
a second conductive layer located above the first conductive layer;
an isolation structure located between the first sub-conductive structure and the second sub-conductive structure, connected to the second conductive layer, and configured to electrically isolate the first sub-conductive structure from the second sub-conductive structure; and
a contact plug located between the second conductive structure and the second conductive layer and configured to electrically connect the second conductive structure to the second conductive layer.

2. The semiconductor structure according to claim 1, wherein
a top surface of the isolation structure is flush with a top surface of the contact plug, a bottom surface of the isolation structure is lower than a bottom surface of the contact plug, and the bottom surface of the isolation structure is not higher than a bottom surface of the first conductive layer.

3. The semiconductor structure according to claim 1, wherein
the isolation structure and the contact plug each comprise a conductive pillar and an insulating layer disposed around a side wall of the conductive pillar.

4. The semiconductor structure according to claim 1, further comprising:
a first dielectric layer located on the substrate and comprising a first sub-dielectric layer and a second sub-dielectric layer, wherein the first sub-dielectric layer is located on a side wall of the first conductive layer and below the first conductive layer, and the second sub-dielectric layer covers a top surface of the first conductive layer and the first sub-dielectric layer; and
a second dielectric layer located on the first dielectric layer.

5. The semiconductor structure according to claim 4, wherein a sum of a dimension of the second sub-dielectric layer along a thickness direction of the substrate and a dimension of the second dielectric layer along the thickness direction of the substrate is greater than or equal to a preset value;
the isolation structure penetrates through the second dielectric layer and the second sub-dielectric layer, and extends into the first sub-dielectric layer;
the contact plug penetrates through the second dielectric layer and the second sub-dielectric layer, and is in contact with the second conductive structure.

6. The semiconductor structure according to claim 4, wherein
a sum of a dimension of the second sub-dielectric layer along a thickness direction of the substrate and a dimension of the second dielectric layer along the thickness direction of the substrate is less than a preset value;
the semiconductor structure further comprises: a third dielectric layer located on the second dielectric layer;
the isolation structure penetrates through the third dielectric layer, the second dielectric layer, and the second sub-dielectric layer, and extends into the first sub-dielectric layer;
the contact plug penetrates through the third dielectric layer, the second dielectric layer, and the second sub-dielectric layer, and is in contact with the second conductive structure.

7. The semiconductor structure according to claim 6, wherein
materials of the first dielectric layer and the second dielectric layer are different, and materials of the second dielectric layer and the third dielectric layer are different.

8. The semiconductor structure according to claim 1, wherein
a dimension of the isolation structure in a first horizontal direction is greater than a dimension of the contact plug in the first horizontal direction, a dimension of the isolation structure in a second horizontal direction is greater than or equal to dimensions of the first sub-conductive structure and the second sub-conductive structure in the second horizontal direction, the first horizontal direction is an arrangement direction of the first sub-conductive structure and the second sub-conductive structure, and the second horizontal direction is an extension direction of the first sub-conductive structure and the second sub-conductive structure.

9. The semiconductor structure according to claim 1, wherein
the substrate comprises an active region and a gate structure located on the active region, and the active region comprises a first source/drain region and a second source/drain region located on opposite sides of the gate structure, respectively;
the semiconductor structure further comprises: a first connection pillar and a second connection pillar, wherein the first connection pillar electrically connects the first sub-conductive structure to the first source/drain region, and the second connection pillar electrically connects the second sub-conductive structure to the second source/drain region.

10. A method for manufacturing a semiconductor structure, comprising:
providing a substrate;
forming an initial first conductive layer on the substrate, wherein the initial first conductive layer comprises a first conductive structure and a second conductive structure spaced apart from each other;
forming a first trench and a second trench in a same step, wherein the first trench penetrates through the first conductive structure to divide the first conductive structure into a first sub-conductive structure and a second sub-conductive structure, the second trench is located on the second conductive structure and exposes a part of a surface of the second conductive structure, and the first sub-conductive structure, the second sub-conductive structure, and the second conductive structure are formed as a first conductive layer;
forming an isolation structure in the first trench;
forming a contact plug in the second trench; and
forming a second conductive layer on the isolation structure and the contact plug.

11. The method according to claim 10, further comprising:
before forming the initial first conductive layer, forming a first sub-dielectric layer on the substrate, wherein the first sub-dielectric layer is located on a side wall of the initial first conductive layer and below the initial first conductive layer;
forming a second sub-dielectric layer covering the initial first conductive layer and the first sub-dielectric layer, wherein the first sub-dielectric layer and the second sub-dielectric layer are formed as a first dielectric layer; and
forming a second dielectric layer on the first dielectric layer.

12. The method according to claim 11, wherein
a sum of a dimension of the second sub-dielectric layer along a thickness direction of the substrate and a dimension of the second dielectric layer along the thickness direction of the substrate is greater than or equal to a preset value;
forming the first trench and the second trench in the same step comprises:
performing a first etching process, wherein the first trench penetrates through the second dielectric layer and stops at a surface of the first dielectric layer, the second trench stops within the second dielectric layer, a dimension of the first trench in a first horizontal direction is greater than a dimension of the second trench in the first horizontal direction, and the first horizontal direction is an arrangement direction of the first sub-conductive structure and the second sub-conductive structure;
performing a second etching process, wherein the first trench penetrates through the second sub-dielectric layer and stops at a surface of the first conductive structure, the second trench stops within the second dielectric layer, and the first dielectric layer has a different etching selectivity from the second dielectric layer; and
performing a third etching process, wherein the first trench penetrates through the first conductive structure, and the second trench exposes the part of the surface of the second conductive structure.

13. The method according to claim 11, wherein
a sum of a dimension of the second sub-dielectric layer along a thickness direction of the substrate and a dimension of the second dielectric layer along the thickness direction of the substrate is less than a preset value;
the method further comprises: forming a third dielectric layer on the second dielectric layer;
forming the first trench and the second trench in the same step comprises:
performing a fourth etching process, wherein the first trench penetrates through the third dielectric layer and stops at a surface of the second dielectric layer, the second trench stops within the third dielectric layer, a dimension of the first trench in a first horizontal direction is greater than a dimension of the second trench in the first horizontal direction, and the first horizontal direction is an arrangement direction of the first sub-conductive structure and the second sub-conductive structure;
performing a fifth etching process, wherein the first trench penetrates through the second dielectric layer and the second sub-dielectric layer and stops at a surface of the first conductive structure, the second trench penetrates through the third dielectric layer and stops within the second dielectric layer, and the second dielectric layer has a different etching selectivity from the third dielectric layer; and
performing a sixth etching process, wherein the first trench penetrates through the first conductive structure, and the second trench exposes the part of the surface of the second conductive structure.

14. The method according to claim 1, wherein forming the isolation structure in the first trench and forming the contact plug in the second trench comprise:
forming an insulating layer on side walls of the first trench and the second trench; and
filling a conductive material into the first trench and the second trench, both of which are formed with the insulating layer, to form the isolation structure in the first trench and form the contact plug in the second trench.

15. The method according to claim 1, wherein the substrate comprises an active region and a gate structure located on the active region, and the active region comprises a first source/drain region and a second source/drain region located on opposite sides of the gate structure, respectively;
forming the initial first conductive layer on the substrate comprises:
forming a first connection pillar and a second connection pillar, and the initial first conductive layer on the first connection pillar and the second connection pillar, wherein the first connection pillar is in contact with the first source/drain region, and the second connection pillar is in contact with the second source/drain region.
